(19) United States
(12) Patent Application Publication
(10) Pub. No.: US 2026/0282856 A1
(43) Pub. Date: Sep. 17, 2026

(54) RUTHENIUM SEEDING FOR CORROSION FREE MOLYBDENUM GROWTH

(71) Applicant: Applied Materials, Inc., Santa Clara, CA (US)

(72) Inventors: Ruinan Zhou, Santa Clara, CA (US); Ge Qu, Sunnyvale, CA (US); Shiyu Hu, Cupertino, CA (US); Changhyun Choi, Santa Clara, CA (US); Yu-Heng Deng, San Jose, CA (US); Jiajie Cen, San Jose, CA (US); Kevin Kashefi, San Ramon, CA (US)

(73) Assignee: Applied Materials, Inc., Santa Clara, CA (US)

(21) Appl. No.: 19/560,478

(22) Filed: Mar. 9, 2026

Related U.S. Application Data
(60) Provisional application No. 63/771,153, filed on Mar. 13, 2025.

(51) Int. Cl. H10W 20/00; C23C 16/02; C23C 16/04; C23C 16/455; H10W 20/44

(52) U.S. Cl. CPC H10W 20/045; C23C 16/0227; C23C 16/0281; C23C 16/045; C23C 16/45525; H10W 20/057; H10W 20/4446

(57) ABSTRACT

Provided are methods of forming a seed layer on a conductive metal layer of a semiconductor device. The method includes exposing the top surface of a substrate to a first reactant and a ruthenium precursor to deposit a seed layer on the top surface of the substrate. The substrate has at least one feature formed in a dielectric layer. The at least one feature defines a gap including sidewalls and a bottom. After deposition of the seed layer, the gap is filled with a metal by a gap filling process.

### CROSS-REFERENCE TO RELATED APPLICATIONS

This application claims priority to United States Provisional Application No. 63/771,153, filed Mar. 13, 2025, the entire disclosure of which is hereby incorporated by reference herein.

### TECHNICAL FIELD

Embodiments of the present disclosure relate to the field of semiconductor manufacturing. More particularly, embodiments of the disclosure relate to methods of depositing a molybdenum gap fill layer.

### BACKGROUND

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both metal lines and metal vias and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increase power consumption. A conventional interconnect structure, such as a copper interconnect structure, includes a barrier layer and/or a metal liner deposited on the sidewalls of a gap that provide a via, the sidewalls made of a dielectric material, providing good adhesion and preventing the copper from diffusing into the dielectric layer. Barrier layers can typically be the largest contributor to via resistance due to their own high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume.

In current interconnect manufacturing processes, a molybdenum halide soak is used to facilitate subsequent metal fill in the gap between the sidewalls. The high level of chlorine released during molybdenum halide soak dissociation leads to the etching of copper, which restricts the application of molybdenum nucleation by molybdenum halide soak and makes the bottom-up molybdenum gap fill process more challenging.

Accordingly, there is a need for improved methods of depositing molybdenum gap fill.

### SUMMARY

One or more embodiments of the present disclosure are directed to a method of forming a semiconductor device. The method comprises: exposing a top surface of a substrate to a first reactant and a ruthenium precursor to deposit a seed layer on the top surface of conductive metal layer on the substrate, the substrate comprising at least one feature formed in a dielectric layer, the dielectric layer defining a gap including sidewalls and a bottom, the seed layer depositing on the conductive metal layer; and exposing the seed layer to a second reactant and a metal precursor to selectively deposit a gap fill material on the seed layer.

Additional elements of the present disclosure are directed toward a method of forming a semiconductor device. In one or more embodiments, the method comprises: forming a dielectric layer on a conductive metal layer on a substrate, the dielectric layer including at least one feature defining a gap having sidewalls and a bottom; pre-cleaning the substrate; depositing a seed layer on the conductive metal layer by exposing a top surface of a substrate to a first reactant and a ruthenium precursor; and performing a gap fill process to fill the gap with a gap fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments, as described herein, are illustrated by way of example and not limited in the figures of the accompanying drawings in which like references indicate similar elements.

FIG. 1 illustrates a process flow diagram of a method of forming a semiconductor device in accordance with one or more embodiments of the disclosure;

FIG. 2A illustrates a cross-sectional schematic view of a semiconductor in accordance with one or more embodiments of the disclosure;

FIG. 2B illustrates a cross-sectional schematic view of a semiconductor device in accordance with one or more embodiments of the disclosure;

FIG. 2C illustrates a cross-sectional schematic view of a semiconductor device in accordance with one or more embodiments of the disclosure;

FIG. 3A illustrates a cross-sectional schematic view of a semiconductor device in accordance with one or more embodiments of the disclosure; and

FIG. 3B illustrates a cross-sectional schematic view of a semiconductor device in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term "about" as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

As used in this specification and the appended claims, the term "substrate" and "wafer" are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A "substrate" as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term "substrate surface" is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms "precursor", "reactant", "reactive gas" and the like are used interchangeably to refer to any gaseous species that can react with the substrate surface, or with a film formed on the substrate surface.

In some embodiments, "selectively" means that the subject material forms on the selected surface at a rate greater than or equal to about 2x, 3x, 4x, 5x, 7x, 10x, 15x, 20x, 25x, 30x, 35x, 40x, 45x or 50x the rate of formation on the non-selected surface. Stated differently, the selectivity of the stated process for the selected surface relative to the non-selected surface is greater than or equal to about 2:1, 3:1, 4:1, 5:1, 7:1, 10:1, 15:1, 20:1, 25:1, 30:1, 35:1, 40:1, 45:1 or 50:1.

As used herein, the term "substantially free" means that there is less than about 5%, including less than about 4%, less than about 3%, less than about 2%, less than about 1%, and less than about 0.5% of halide or directly oxygen bonding metal, on an atomic basis, in the reactant or carrier gas.

"Atomic layer deposition" or "cyclical deposition" as used herein refers to the sequential exposure of two or more reactive compounds to deposit a layer of material on a substrate surface. As used in this specification and the appended claims, the terms "reactive compound", "reactive gas", "reactive species", "precursor", "process gas" and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term "substantially" used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A with a carrier gas, e.g., argon (Ar)) is pulsed into the reaction zone followed by a first-time delay. Next, a second precursor or compound B with a carrier gas, e.g., argon (Ar), is pulsed into the reaction zone followed by a second delay. During each time-delay, a purge gas, such as argon, is used to purge the reaction zone or otherwise remove any residual reactive compound or by-products from the reaction zone. The reactive compounds are alternatively pulsed until a desired film or film thickness is formed on the substrate surface. In either scenario, the ALD process of pulsing compound A, purge gas, compound B, and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

In current interconnect manufacturing processes, a molybdenum halide soak is often used to facilitate subsequent metal fill in the gap between the sidewalls. The high level of halide, e.g., chloride, released during molybdenum halide soak dissociation leads to the etching of copper, which restricts the application of molybdenum nucleation by molybdenum halide soak and makes the bottom-up molybdenum gap fill process more challenging. In one or more embodiments, ruthenium (Ru) seeding on the copper (Cu) layer advantageously expands the process window by protecting the copper (Cu) from corrosion. Additionally, in one or more embodiments, the use of ruthenium (Ru) seeding on copper (Cu) advantageously eliminates the need for nucleation in selective molybdenum growth on ruthenium (Ru), and reduces the requirement for the molybdenum halide soak, thereby mitigating the copper-halide, e.g., Cu-Cl, interaction.

The embodiments of the disclosure are described by way of the Figures, which illustrate devices (e.g., semiconductor devices with interconnects) and processes for forming semiconductor devices in accordance with one or more embodiments of the disclosure. The processes shown are merely illustrative possible uses for the disclosed processes, and the skilled artisan will recognize that the disclosed processes are not limited to the illustrated applications.

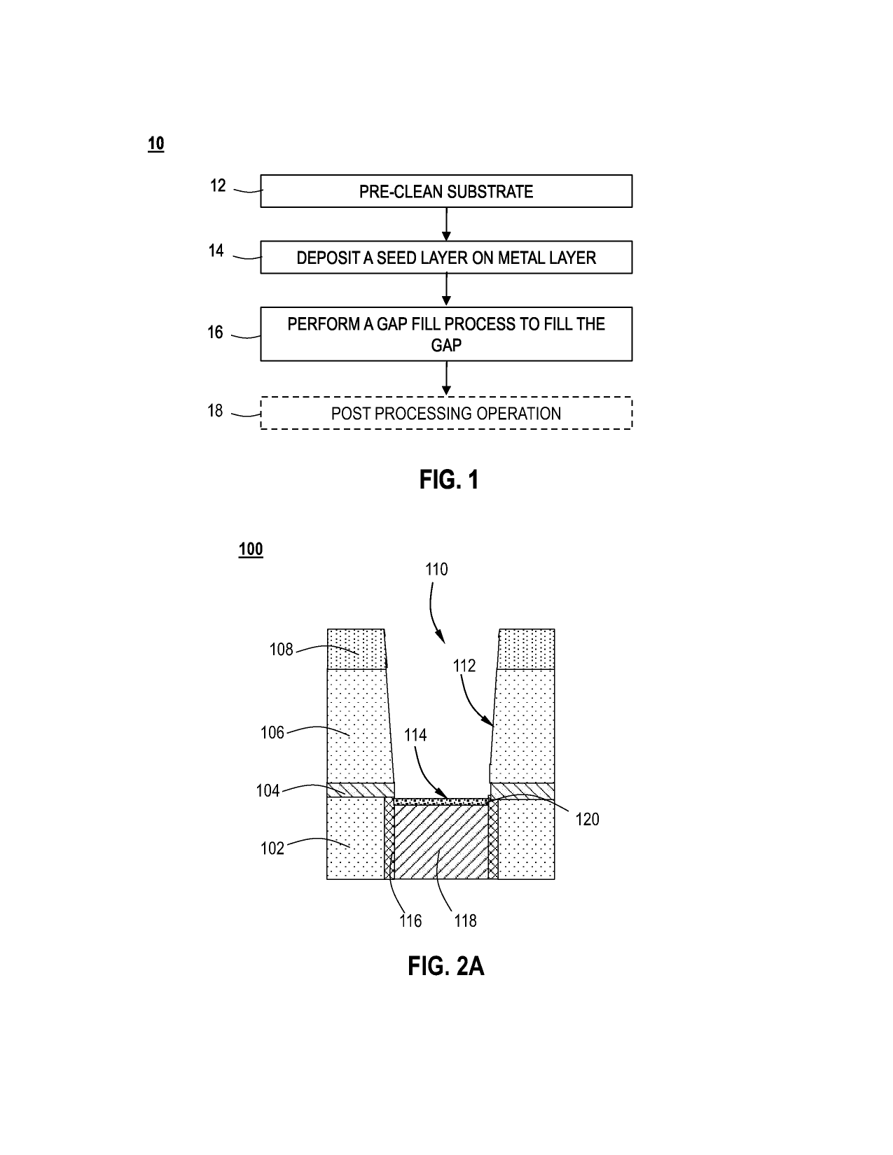

FIG. 1 illustrates a process flow diagram of a method 10 for forming a semiconductor device in accordance with one or more embodiments of the disclosure.

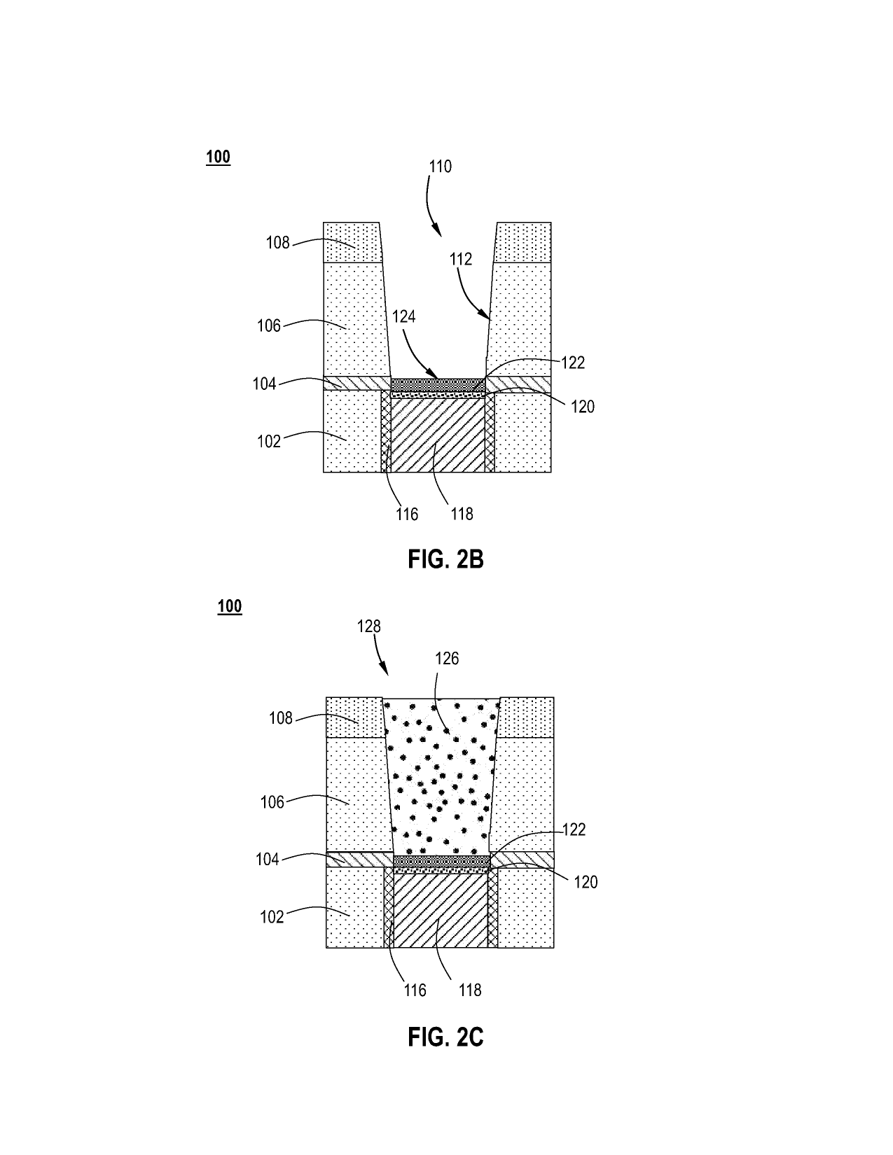

In some embodiments, the method 10 is a method of manufacturing a semiconductor device 100 as illustrated in FIGS. 2A to 2C. Referring to FIGS. 2A – 2C, a portion of a semiconductor device 100 is shown during stages of manufacture. The semiconductor device 100 may be an intermediate structure used in the fabrication of a semiconductor device. While a particular structure of a semiconductor device is described as an example, it will be appreciated by the skilled artisan that any architecture with different designs of interconnect, may be provided in accordance with various embodiments.

In some embodiments, the method 10 is a method of forming gap layer on a substrate. The substrate may have features on a surface of the substrate on which a film is deposited with high selectivity using the method 10.

With reference to FIG. 1, one or more embodiments of the disclosure are directed to method 10 of depositing a metal film, a gap fill layer more particularly. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In one or more embodiments, the method comprises a chemical vapor deposition (CVD) process in which the reactive gases are mixed in the processing chamber to allow gas phase reactions of the reactive gases and deposition of the thin film.

In one or more embodiments, the method 10 includes a pre-cleaning operation 12. The method 10 may include pre-cleaning the substrate 102. The pre-clean process of operation 12 of the method 10 may include one or more wet or dry etch processing, such as a remote plasma assisted dry etch process, in which the surface of the substrate 102 is exposed to nitrogen trifluoride (NF₃) gas, nitrogen (N₂) gas, or ammonia (NH₃) gas, and subsequently etching the surface of the substrate 102 to remove oxide-containing contaminants (e.g., native oxide layers), by a wet etch process using an etch solution, such as hydrochloric acid (HCl) solution and/or dilute hydrofluoric acid (DHF) solution.

The pre-clean process of operation 12 may be performed in any suitable pre-clean chamber known to the skilled artisan. In one or more embodiments, the pre-clean process may be performed without breaking vacuum environment in a multi-chamber processing system to prevent contamination from moisture, organic or nonorganic trance species.

At deposition 14, a process is performed to deposit a seed layer on the metal layer of the substrate (or substrate surface) to facilitate subsequent gap filling. At the deposition of operation 16, a process is performed to deposit a gap fill layer on the seed layer. The deposition process of operation 16 can include one or more operations to form the gap fill layer on the seed layer. In operation 16, the seed layer and device structure are exposed to a reactant to deposit a reactant species on the substrate (or substrate surface). The reactant can be any suitable reactant compound that can react with (i.e., adsorb or chemisorb onto) the substrate surface to leave a reactant species on the substrate surface. After the gap gill layer is deposited, one or more optional post-processing operations 18 occur.

The optional post-processing operation 18 can be, for example, a process to modify film properties (e.g., annealing) or a further film deposition process (e.g., additional ALD or CVD processes) to grow additional films. In some embodiments, the optional post-processing operation 18 can be a process that modifies a property of the device and gap fill layer. In some embodiments, the optional post-processing operation 18 comprises annealing the device. In some embodiments, annealing is done at temperatures in the range of about 300º C, 400º C, 500º C, 600º C, 700º C, 800º C, 900º C, or 1000º C.

The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the device is annealed for a predetermined time in the range of about 15 seconds to about 90 minutes, or in the range of about 1 minute to about 60 minutes. In some embodiments, annealing the as-deposited device increases the density, decreases the resistivity, and/or increases the purity of the gap fill layer.

The method 10 can be performed at any suitable temperature depending on, for example, the reactant, the metal precursor, or thermal budget of the device. In one or more embodiments, the use of high temperature processing may be undesirable for temperature-sensitive substrates. In one or more embodiments, deposition of the seed layer and the gap fill layer occur at the same temperature. In one or more embodiments, the substrate is maintained at a temperature in a range of about 20° C to about 400° C, or about 50° C to about 500° C.

In one or more embodiments, exposure of the substrate to different temperatures is facilitated by a multi-station processing platform. In one or more embodiments, the multi-station processing platform performs a spatial ALD process thereby allowing multiple substrates to be processed in different processing stations at different temperatures within the same chamber.

FIGS. 2A through 2C illustrate cross-sectional schematic views of a portion of a semiconductor device 100 being processed according to the method of one or more embodiments. In some embodiments, the semiconductor device is part of a single damascene process. With reference to FIG. 2A, an initial or starting substrate or intermediate semiconductor device 100 is provided or formed in accordance with one or more embodiments of the disclosure. As used in this specification and the appended claims, the term "provided" means that the semiconductor device 100 is made available for processing (e.g., positioned in a processing chamber).

More specifically, FIG. 2A illustrates a cross-section view of the semiconductor device 100 comprising a feature defining a gap 110. The semiconductor device 100 comprises a substrate 102, a barrier layer 116 on the substrate 102, a conductive metal layer 118, an etch stop layer 104, a dielectric layer 106 on the etch stop layer 104, the dielectric layer 106 comprising at least one feature defining a gap 110 including sidewalls 112 and a bottom 114. In one or more embodiments, an optional capping layer 120 may be formed on the top surface of the conductive metal layer 118.

In one or more embodiments, the substrate 102 is a wafer, for example a semiconductor substrate. In one or more embodiments, the barrier layer 116 comprises any suitable barrier material known to the skilled artisan. In one or more specific embodiments, the barrier layer 116 comprises tantalum nitride (TaN). In one or more embodiments, the conductive metal layer 118 comprises any suitable metal known to the skilled artisan. In one or more embodiments, the conductive metal layer 118 comprises one or more of copper (Cu), ruthenium (Ru), manganese (Mn), cobalt (Co), molybdenum (Mo), tungsten (W), and tantalum (Ta). In one or more embodiments, the conductive metal layer 118 comprises one or more of ruthenium (Ru) or copper (Cu).

In one or more embodiments, a capping layer 120 may be formed on the top surface of the conductive metal layer 118. The capping layer 120 may have any suitable thickness. In some embodiments, the capping layer 120 has a thickness in a range of from 5 Å to 25 Å. In one or more embodiments, the capping layer 120 comprises any suitable metal known to the skilled artisan. In one or more embodiments, the capping layer 120 comprises one or more of cobalt (Co), copper (Cu), ruthenium (Ru), manganese (Mn), molybdenum (Mo), and tungsten (W). In one or more embodiments, the capping layer 120 comprises one or more of cobalt (Co) or ruthenium (Ru).

In one or more embodiments, the etch stop layer 104 comprises any suitable etch stop material known to the skilled artisan. In one or more embodiments, the etch stop layer 104 comprises one or more of aluminum oxide, silicon nitride, and aluminum nitride.

In one or more embodiments, the dielectric layer 106 comprises any suitable dielectric material known to the skilled artisan. In one or more embodiments, the dielectric layer 106 comprises a low-k dielectric layer. In certain embodiments, the dielectric layer 106 comprises silicon oxide (SiOₓ). In one or more embodiments, the dielectric layer 106 comprises SiOₓH_{y}(CH_{z}). Further embodiments provide that the dielectric layer 106 comprises porous or carbon-doped SiOₓ. In some embodiments, the dielectric layer 106 is a porous or carbon-doped SiOₓ layer with a k value less than about 5. In other embodiments, the dielectric layer 106 is a multilayer structure. For example, in one or more embodiments, the dielectric layer 106 comprises a multilayer structure having one or more of a dielectric layer, an etch stop layer, and a hard mask layer 108.

In one or more embodiments, the dielectric layer 106 comprises at least one feature defining a gap 110 including sidewalls 112 and a bottom 114. The Figures show substrates having a single feature for illustrative purposes; however, those skilled in the art will understand that there can be more than one feature. The shape of the feature can be any suitable shape including, but not limited to, trenches, cylindrical vias that, when filled with metal, transfer current between layers, and lines that transfer current within the same device layer. In some embodiments, the feature defines a gap 110 in the dielectric layer. As used herein, the term "feature" means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

FIG. 2B illustrates a cross-sectional schematic view of the semiconductor device 100 where a seed layer 122, is formed on the bottom 114, e.g., a top surface of the capping layer 120, if present, on conductive metal layer 118. In one or more embodiments, the seed layer 122 may be formed by any suitable deposition process known to the skilled artisan, including, but not limited to, atomic layer deposition (ALD) and chemical vapor deposition (CVD). In one or more embodiments, the seed layer 122 may be formed by exposing a top surface of a substrate to a reactant and a ruthenium precursor to deposit the seed layer 122 on the top surface of conductive metal layer 118 on the substrate.

Any suitable reactant may be used. The reactant according to one or more embodiments is a thermal reactant (e.g., without the use of plasma) or a plasma composed of the reactant. In embodiments where the reactant comprises a plasma composed of the reactant, the plasma may be generated by any suitable plasma source. The plasma may include, but is not limited to, one or more of an inductively coupled plasma (ICP) source, a capacitively coupled plasma (CCP) source, a microwave source, or a remote plasma source. In one or more embodiments, the reactant may comprise one or more of hydrogen (H₂), hydrogen radical (H*), and hydrogen ion (H+).

Any suitable ruthenium precursor known to the skilled artisan may be used. In some embodiments, the ruthenium precursor has a general formula of [L]ₘRu(CO)₃, wherein L is a linear or branched unsaturated hydrocarbon, a linear or branched saturated hydrocarbon, a cyclic unsaturated hydrocarbon, or a cyclic saturated hydrocarbon, L has one or more R substituents where R is an alkyl group, and m is an integer in a range of from 1 to 4.

Unless otherwise indicated, the term "lower alkyl," "alkyl," or "alk" as used herein alone or as part of another group includes both straight and branched chain hydrocarbons, containing 1 to 20 carbons, or 1 to 10 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

In one or more embodiments, the ruthenium precursor may comprise one or more of Ru(ethylene)₂(CO)₃, Ru(propylene)₂(CO)₃, Ru(butene)₂(CO)₃, Ru(2,4-pentadiene)(CO)₃, Ru(2-methyl-2,4-pentadiene)(CO)₃, Ru(1,4-pentadiene)(CO)₃, Ru(2,4-hexadiene)(CO)₃, Ru(2,4-hexadienal)(CO)₃, Ru(2,4-heptadiene)(CO)₃, Ru(1,4-dimethyl-1,3-cyclohexadiene)(CO)₃, Ru(1-methyl-4-ethyl-1,3-cyclohexadiene)(CO)₃, Ru(1-methyl-4-n-propyl-1,3-cyclohexadiene)(CO)₃, Ru(1-methyl-4-isopropyl-1,3-cyclohexadiene)(CO)₃, Ru(1,5-dimethyl-1,4-cyclohexadiene)(CO₃), Ru(1-methyl-5-ethyl-1,4-cyclohexadiene)(CO)₃, Ru(1-methyl-1,4-cyclohexadiene)(CO)_{3,} Ru(1-methyl-5-n-propyl-1,4-cyclohexadiene)(CO)₃, and Ru(1-methyl-5-isopropyl-1,4-cyclohexadiene)(CO)₃. In one or more embodiments, the ruthenium precursors comprises Ru(1-methyl-1,4-cyclohexadiene)(CO)₃.

The seed layer 122 may comprise any suitable material known to the skilled artisan. In one or more embodiments, the seed layer 122 comprises a metal material. In one or more specific embodiments, the seed layer 122 comprises ruthenium (Ru).

In some embodiments, the seed layer 122 comprises greater than or equal to about 95 atomic percent ruthenium, or greater than or equal to about 97atomic percent ruthenium, or greater than or equal to about 98 atomic percent ruthenium, or greater than or equal to about 99 atomic percent ruthenium, or greater than or equal to about 99.5 atomic percent ruthenium, or greater than or equal to about 99.8 atomic percent ruthenium.

In some embodiments, the seed layer 122 contains essentially no halogen atoms. As used in this manner, the term "contains essentially no halogen atoms" means the seed layer 122 about 0% of halogen atoms on an atomic basis. In some embodiments, the seed layer 122 is free of halogen atoms. It is noted that, as recognized by one of skill in the art, while the reactant and ruthenium precursor do not contact halogen atoms, a halide contaminant could be present from another source. Thus, the seed layer 122 may contain a small amount, e.g., less than 5% on an atomic basis, of a halide contaminant.

In one or more embodiments, the seed layer 122 has any suitable thickness. In one or more embodiments, the seed layer 122 has a thickness in a range of from greater than 0 Å to less than 10 Å, including in a range of from greater than 0 Å to 7 Å, and in a range of from greater than 0 Å to 5 Å. In one or more embodiments, the seed layer 122 has a thickness of about 0.2 Å, or about 0.5 Å, or about 1.0 Å, or about 1.5 Å, or about 2.0 Å, or about 2.5 Å, or about 3.0 Å, or about 3.5 Å, or about 4.0 Å, or about 4.5 Å, or about 5.0 Å.

In some embodiments, the seed layer 122 is deposited in a single ALD cycle. In other embodiments, the seed layer 122 is deposited in from 1 to 200ALD cycles. In one or more embodiments, each cycle of the 1 to 200 ALD cycles is configured to deposit a thickness of about 0.1 Å of the seed layer 122.

In one or more embodiments, the seed layer 122 formed on the conductive metal layer 118 advantageously expands the process window by protecting the conductive metal layer from corrosion. No barrier layer or liner layer is needed for the subsequent gap fill process, which lowers the resistance of the device. Additionally, in one or more embodiments, the seed layer 122 on the conductive metal layer 118 advantageously eliminates the need for nucleation in selective molybdenum growth on the seed layer 122, and reduces the requirement for a molybdenum halide soak, thereby mitigating the metal-halide, e.g., Cu-Cl, interaction.

FIG. 2C illustrates a cross-sectional schematic view of the semiconductor device 100 where a gap fill material 126 has been deposited on the seed layer 122. In one or more embodiments, a bottom-up gap fill process may be used to fill the feature defining a gap 110 from the bottom on the top surface 124 of the seed layer 122 versus a conformal process which fills the feature or gap 110 from the bottom and sides. to form a filled gap 128. In other embodiments, a conformal process may be used to fill the feature defining a gap 110 with a gap fill material 126 to form a filled gap 128. The gap fill material 126 may comprise any suitable gap fill material known to the skilled artisan. According to one or more embodiments, the filled gap 128 comprises a gap fill material 126 is a metal selected from one or more copper (Cu), ruthenium (Ru), manganese (Mn), cobalt (Co), molybdenum (Mo), and tungsten (W). In one or more specific embodiments, the filled gap 128 comprises molybdenum (Mo) as the gap fill material 126.

In one or more embodiments, the gap fill material 126 is substantially free of seams and/or voids or free of seams and/or voids. As used in this regard, "substantially free" means that less than about 5%, including less than about 4%, less than about 3%, less than about 2%, less than about 1%, less than about 0.5%, and less than about 0.1% of the total composition of the gap fill material 126 an atomic basis, comprises seams and/or voids. Advantageously, in one or more embodiments, gap fill material 126 is free of seams and/or voids.

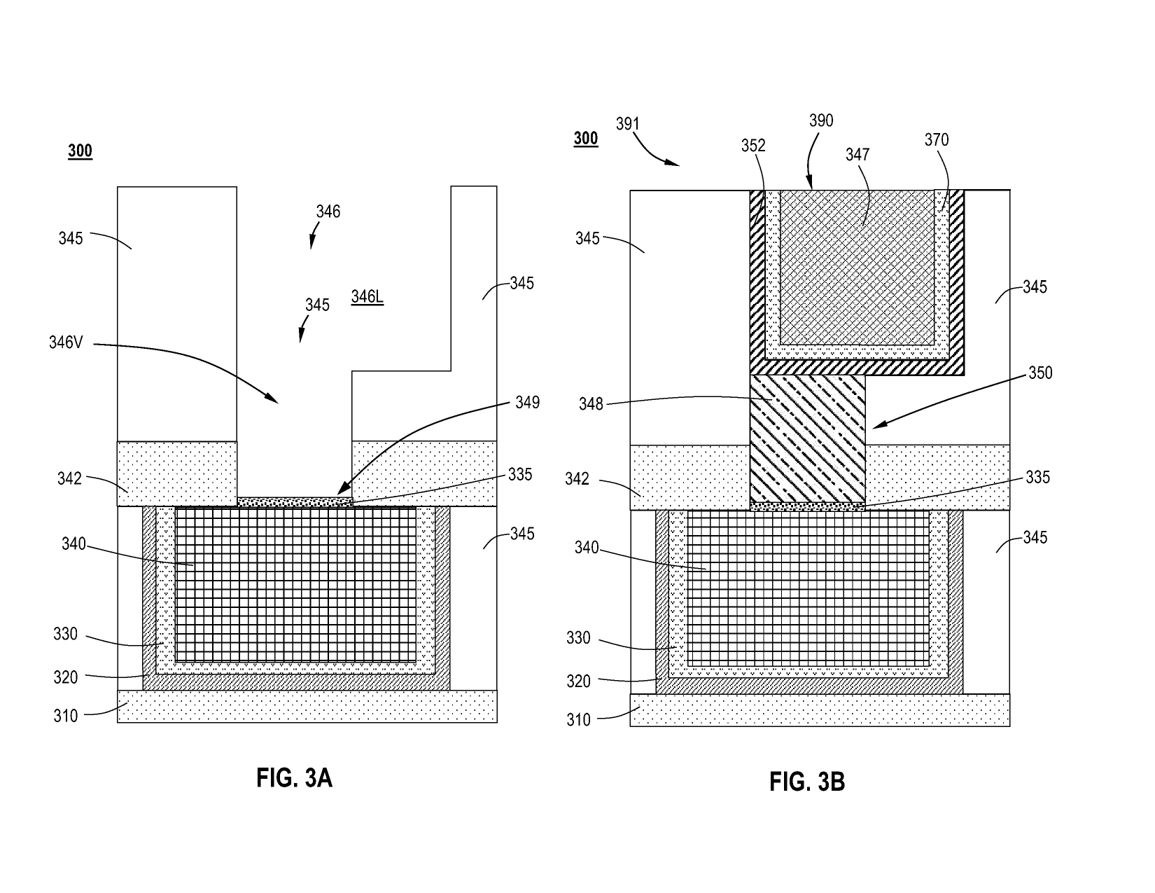

FIGS. 3A and 3B illustrate cross-sectional schematic views of a portion of a semiconductor device 300 being processed according to the method of one or more embodiments. In some embodiments, the semiconductor device is part of a dual damascene process, as illustrated in FIGS. 3A and 3B. With reference to FIG. 3A, an initial or starting substrate or intermediate semiconductor device 300 is provided or formed in accordance with one or more embodiments of the disclosure. As used in this specification and the appended claims, the term "provided" means that the substrate 300 is made available for processing (e.g., positioned in a processing chamber).

More specifically, FIG. 3A illustrates a cross-section view of the semiconductor device 300 comprising a substrate 310, a barrier layer 320 on the substrate 310, a metal layer 330 on the barrier layer 320, a conductive filled gap 340, an etch stop layer 342, and a dielectric layer 345 on the etch stop layer 342. The dielectric layer 345 comprises at least one feature defining the gap 346. It will be appreciated that in one or more embodiments, the conductive filled gap 340 forms a metal line that transfers current within the same device layer.

In one or more embodiments, the substrate 310 is a wafer, for example, a semiconductor substrate. In one or more embodiments, the substrate 310 is an etch stop layer on a wafer. In one or more embodiments, the substrate 310 is an aluminum oxide etch stop layer on a wafer. In one or more embodiments, the barrier layer 320 comprises tantalum nitride (TaN). In one or more embodiments, the barrier layer 320 comprises tantalum nitride (TaN) formed by ALD.

In one or more embodiments, the metal layer 330 comprises one or more of ruthenium (Ru), copper (Cu), cobalt (cobalt), ruthenium (Ru), tantalum (Ta), or tungsten (W). In one or more embodiments, the conductive filled gap 340 comprises one or more of copper (Cu) or cobalt (Co). In one or more embodiments, the etch stop layer 342 comprises one or more of aluminum oxide, silicon nitride, or aluminum nitride.

In one or more embodiments, the dielectric layer 345 comprises a low-κ dielectric material. In one or more embodiments, the dielectric layer 345 comprises silicon oxide (SiOₓ). In one or more embodiments, the dielectric layer 345 comprises SiOₓH_{y}(CH_{z}). Further embodiments provide that the dielectric layer 345 comprises porous or carbon-doped SiOₓ. In some embodiments, the dielectric layer 345 is a porous or carbon-doped SiOₓ layer with a κ value less than about 5. In other embodiments, the dielectric layer 345 is a multilayer structure. For example, in one or more embodiments, the dielectric layer 345 comprises a multilayer structure having one or more of a dielectric layer, an etch stop layer, and a hard mask layer.

In one or more illustrated embodiments, the dielectric layer 345 comprises at least one feature defining the gap 346. FIGS. 3A and 3B illustrate substrate 310 having a single feature for illustrative purposes; however, those skilled in the art will understand that there can be more than one feature.

In some embodiments, the at least one feature defines a cylindrical via that, when filled with metal, transfers current between layers, and lines that transfer current within the same device layer. In some embodiments, the at least one feature defines the gap 346 in the dielectric layer 345. In some embodiments, the gap 346 defines a via portion 346V and a line portion 346L. The bottom 349 of the gap 346 is defined by the metal layer 330. In one or more embodiments, the bottom 349 of the gap 346 and the metal layer 330 comprise the same material. In one or more embodiments, the bottom 349 of the gap 346 comprises one or more of ruthenium (Ru), copper (Cu), cobalt (cobalt), ruthenium (Ru), tantalum (Ta), or tungsten (W).

FIG. 3A illustrates a cross-sectional schematic view of the semiconductor device 300 where a seed layer 335, is formed on a top surface of the conductive filled gap 340. In one or more embodiments, the seed layer 335 may be formed by any suitable deposition process known to the skilled artisan, including, but not limited to, atomic layer deposition (ALD) and chemical vapor deposition (CVD). In one or more embodiments, the seed layer 335 may be formed by exposing a top surface of a substrate to a reactant and a ruthenium precursor to deposit the seed layer 335 on the top surface of conductive filled gap 340 on the substrate.

Any suitable reactant may be used. The reactant according to one or more embodiments is a thermal reactant (e.g., without the use of plasma) or a plasma composed of the reactant. In embodiments where the reactant comprises a plasma composed of the reactant, the plasma may be generated by any suitable plasma source. The plasma may include, but is not limited to, one or more of an inductively coupled plasma (ICP) source, a capacitively coupled plasma (CCP) source, a microwave source, or a remote plasma source. In one or more embodiments, the reactant may comprise one or more of hydrogen (H₂), hydrogen radical (H*), and hydrogen ion (H+).

Any suitable ruthenium precursor known to the skilled artisan may be used. In some embodiments, the ruthenium precursor has a general formula of [L]ₘRu(CO)₃, wherein L is a linear or branched unsaturated hydrocarbon, a linear or branched saturated hydrocarbon, a cyclic unsaturated hydrocarbon, or a cyclic saturated hydrocarbon, L has one or more R substituents where R is an alkyl group, and m is an integer in a range of from 1 to 4.

Unless otherwise indicated, the term "lower alkyl," "alkyl," or "alk" as used herein alone or as part of another group includes both straight and branched chain hydrocarbons, containing 1 to 20 carbons, or 1 to 10 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

In one or more embodiments, the ruthenium precursor may comprise one or more of Ru(ethylene)₂(CO)₃, Ru(propylene)₂(CO)₃, Ru(butene)₂(CO)₃, Ru(2,4-pentadiene)(CO)₃, Ru(2-methyl-2,4-pentadiene)(CO)₃, Ru(1,4-pentadiene)(CO)₃, Ru(2,4-hexadiene)(CO)₃, Ru(2,4-hexadienal)(CO)₃, Ru(2,4-heptadiene)(CO)₃, Ru(1,4-dimethyl-1,3-cyclohexadiene)(CO)₃, Ru(1-methyl-4-ethyl-1,3-cyclohexadiene)(CO)₃, Ru(1-methyl-4-n-propyl-1,3-cyclohexadiene)(CO)₃, Ru(1-methyl-4-isopropyl-1,3-cyclohexadiene)(CO)₃, Ru(1,5-dimethyl-1,4-cyclohexadiene)(CO₃), Ru(1-methyl-5-ethyl-1,4-cyclohexadiene)(CO)₃, Ru(1-methyl-1,4-cyclohexadiene)(CO)_{3,} Ru(1-methyl-5-n-propyl-1,4-cyclohexadiene)(CO)₃, and Ru(1-methyl-5-isopropyl-1,4-cyclohexadiene)(CO)₃. In one or more embodiments, the ruthenium precursors comprises Ru(1-methyl-1,4-cyclohexadiene)(CO)₃.

The seed layer 335 may comprise any suitable material known to the skilled artisan. In one or more embodiments, the seed layer 335 comprises a metal material. In one or more specific embodiments, the seed layer 335 comprises ruthenium (Ru).

In some embodiments, the seed layer 335 comprises greater than or equal to about 95 atomic percent ruthenium, or greater than or equal to about 97 atomic percent ruthenium, or greater than or equal to about 98 atomic percent ruthenium, or greater than or equal to about 99 atomic percent ruthenium, or greater than or equal to about 99.5 atomic percent ruthenium, or greater than or equal to about 99.8 atomic percent ruthenium.

In some embodiments, the seed layer 335 contains essentially no halogen atoms. As used in this manner, the term "contains essentially no halogen atoms" means the seed layer 335 about 0% of halogen atoms on an atomic basis. In some embodiments, the seed layer 335 is free of halogen atoms. It is noted that, as recognized by one of skill in the art, while the reactant and ruthenium precursor do not contact halogen atoms, a halide contaminant could be present from another source. Thus, the seed layer 335 may contain a small amount, e.g., less than 5% on an atomic basis, of a halide contaminant.

In one or more embodiments, the seed layer 335 has any suitable thickness. In one or more embodiments, the seed layer 335 has a thickness in a range of from greater than 0 Å to less than 10 Å, including in a range of from greater than 0 Å to 7 Å, and in a range of from greater than 0 Å to 5 Å. In one or more embodiments, the seed layer 335 has a thickness of about 0.2 Å, or about 0.5 Å, or about 1.0 Å, or about 1.5 Å, or about 2.0 Å, or about 2.5 Å, or about 3.0 Å, or about 3.5 Å, or about 4.0 Å, or about 4.5 Å, or about 5.0 Å.

In some embodiments, the seed layer 335 is deposited in a single ALD cycle. In other embodiments, the seed layer 335 is deposited in from 1 to 200 ALD cycles. In one or more embodiments, each cycle of the 1 to 200 ALD cycles is configured to deposit a thickness of about 0.1 Å of the seed layer.

In one or more embodiments, the seed layer 335 formed on the conductive filled gap 340 advantageously expands the process window by protecting the conductive metal layer from corrosion. No barrier layer or liner layer is needed for the subsequent gap fill process, which lowers the resistance of the device. Additionally, in one or more embodiments, the seed layer 335 on the conductive filled gap 340 advantageously eliminates the need for nucleation in selective molybdenum growth on the seed layer 335, and reduces the requirement for a molybdenum halide soak, thereby mitigating the metal-halide, e.g., Cu-Cl, interaction.

As illustrated in FIG. 3B, in one or more embodiments, the bottom 349 of the via portion 346V is now a top surface of the seed layer 335. In one or more embodiments, the via portion 346V is subsequently gap filled with a conductive metal layer as the gap fill material 348. In one or more embodiments, the conductive metal layer as the gap fill material 348 comprises any suitable metal known to the skilled artisan. In one or more embodiments, the conductive metal layer as the gap fill material 348 comprises one or more of copper (Cu), ruthenium (Ru), manganese (Mn), cobalt (Co), molybdenum (Mo), tungsten (W), and tantalum (Ta). In one or more embodiments, the conductive metal layer as the gap fill material 348 comprises molybdenum (Mo).

FIG. 3B illustrates a cross-sectional schematic view of the semiconductor device 300 where a gap fill material 348 has been deposited on the seed layer 335. In one or more embodiments, a bottom-up gap fill process may be used to fill the feature defining the gap 346, specifically the via portion 346V of the feature defining the gap 346, from the bottom on the top surface of the seed layer 335 versus a conformal process which fills the feature defining the gap 346 from the bottom and sides to form a filled gap 350. In other embodiments, a conformal process may be used to fill the feature defining the gap 346 with a gap fill material 380 to form a filled gap 350. The gap fill material 348 may comprise any suitable gap fill material known to the skilled artisan. According to one or more embodiments, the filled gap 350 comprises a gap fill material 348 which is a metal selected from one or more of copper (Cu), ruthenium (Ru), manganese (Mn), cobalt (Co), molybdenum (Mo), and tungsten (W). In one or more specific embodiments, the filled gap 350 comprises molybdenum (Mo) as the gap fill material 348.

In one or more embodiments, the gap fill material 348 is substantially free of seams and/or voids or free of seams and/or voids. As used in this regard, "substantially free" means that less than about 5%, including less than about 4%, less than about 3%, less than about 2%, less than about 1%, less than about 0.5%, and less than about 0.1% of the total composition of the gap fill material 348 on an atomic basis, comprises seams and/or voids. Advantageously, in one or more embodiments, gap fill material 348 is free of seams and/or voids.

In one or more embodiments, the line portion 346L of the gap 346 is filled with one or more barrier layer 352, a liner layer 370, and a gap fill material 347. The barrier layer 352 may comprise any suitable barrier material known to the skilled artisan. In one or more specific embodiments, the barrier layer 352 comprises tantalum nitride (TaN). In one or more embodiments, the barrier layer 352 comprises tantalum nitride (TaN) formed by ALD. The liner layer 370 may comprise any suitable liner material known to the skilled artisan. In one or more specific embodiments, the liner layer 370 comprises one or more of ruthenium (Ru), copper (Cu), cobalt (cobalt), ruthenium (Ru), tantalum (Ta), or tungsten (W).

As illustrated in FIG. 3B, a gap fill material 347 has been deposited on one or more of the barrier layer 352, the liner layer 370, and the gap fill material 347. In one or more embodiments, a bottom-up gap fill process may be used to fill the line portion 346L of the feature defining the gap 346, from the bottom versus a conformal process which fills the feature or line portion 346L from the bottom and sides to form a filled gap 390. In other embodiments, a conformal process may be used to fill the feature or line portion 346L with a gap fill material 347 to form a filled gap 390. The gap fill material 347 may comprise any suitable gap fill material known to the skilled artisan. According to one or more embodiments, the filled gap 390 comprises a gap fill material 347 which is a metal selected from one or more of copper (Cu), ruthenium (Ru), manganese (Mn), cobalt (Co), molybdenum (Mo), and tungsten (W). In one or more specific embodiments, the filled gap 390 comprises copper (Cu) as the gap fill material 347.

In one or more embodiments, after filling the gap 346 with the via gap fill material 348 and the line gap fill material 347, a completed interconnect structure, e.g., interconnect structure 391 is formed, such that additional interconnect structures may be formed on top of or below the interconnect structure 391.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film/layer. In some embodiments, the optional post-processing operation comprises annealing the substrate. In some embodiments, the annealing process is performed at temperatures in the range of about 300 ºC, 400 ºC, 500 ºC, 600 ºC, 700 ºC, 800 ºC, 900 ºC or 1000 ºC. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity, and/or increases the purity of the layers, such as ruthenium-containing film 260.

According to one or more embodiments, the substrate is subjected to processing prior to and/or after forming the seed layer. This processing can be performed in the same chamber or in one or more separate processing chambers. In one or more embodiments, the substrate is moved from the first chamber to a separate, second chamber for further processing. The substrate can be moved directly from the first chamber to the separate processing chamber, or it can be moved from the first chamber to one or more transfer chambers and then moved to the separate processing chamber. Accordingly, the processing apparatus may comprise multiple chambers in communication with a transfer station. An apparatus of this sort may be referred to as a "cluster tool" or "clustered system," and the like.

Generally, a cluster tool is a modular system comprising multiple chambers which perform various functions including substrate center-finding and orientation, degassing, annealing, deposition, and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at the front end of the cluster tool. The exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or "load lock" conditions and is not exposed to ambient air when being moved from one chamber to the next. The transfer chambers are thus under vacuum and are "pumped down" under vacuum pressure. Inert gases may be present in the processing chambers or the transfer chambers. In one or more embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In one or more embodiments, the substrate support includes a heater/cooler which can be controlled to change the substrate temperature conductively. In one or more embodiments, the gases (either reactive gases or inert gases) being employed are heated or cooled to locally change the substrate temperature. In one or more embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein with respect to FIG. 1.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### Examples

### Example 1: Deposition of Ruthenium-Containing Seed Layer

General procedure: A substrate comprising copper (Cu) was placed in a processing chamber. The substrate was exposed to a ruthenium precursor carried in an atmosphere of H₂ gas for about 1.2 seconds. Excess metal precursor and byproducts were removed from the chamber by purging for 20 seconds. The deposition cycle was repeated about 50 times to form a ruthenium-containing seed layer on the substrate with a selectivity growth rate of more than 2:1 over the dielectric layer, silicon oxide (SiO₂). The deposition occurred at a temperature in a range of from 150 °to 310 °C.

### Example 2: Deposition of Molybdenum Gap Fill Material

General Procedure: The substrate comprising copper (Cu) and the ruthenium-containing seed layer of Example 1 was exposed to a molybdenum (Mo) precursor carried in an atmosphere of Ar gas for about 3 seconds. Excess molybdenum (Mo) precursor and byproducts were removed from the chamber by purging for 20 seconds. The deposition cycle was repeated about 50 times to form a molybdenum-containing gap fill material in the feature on the substrate with a selectivity growth rate of more than 2:1 over the dielectric layer, silicon oxide (SiO₂). The deposition occurred at a temperature in a range of from 150 °to 450 °C.

Spatially relative terms, such as "beneath," "below," "lower," "above," "upper", "top" and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as "below,” or "beneath" other elements or features would then be oriented "above" the other elements or features. Thus, the exemplary term "below" may encompass both an orientation of above and below. The device may be otherwise oriented (rotated 90 degrees or at other orientations) and the spatially relative descriptors used herein interpreted accordingly.

The use of the terms "a" and "an" and "the" and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., "such as") provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to "one embodiment," "certain embodiments," "one or more embodiments" or "an embodiment" means that a particular feature, structure, material, or characteristic described in connection with the embodiment is included in at least one embodiment of the disclosure. Thus, the appearances of the phrases such as "in one or more embodiments," "in certain embodiments," "in one embodiment" or "in an embodiment" in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of forming a semiconductor device, the method comprising:
exposing a top surface of a substrate to a first reactant and a ruthenium precursor to deposit a seed layer on the top surface of conductive metal layer on the substrate, the substrate comprising at least one feature formed in a dielectric layer, the dielectric layer defining a gap including sidewalls and a bottom, the seed layer depositing on the conductive metal layer; and
exposing the seed layer to a second reactant and a metal precursor to selectively deposit a gap fill material on the seed layer.

2. The method of claim 1, wherein the seed layer has a thickness in a range of from greater than 0 Å to 10 Å.

3. The method of claim 2, wherein the seed layer has a thickness in a range of from greater than 0 Å to 5 Å.

4. The method of claim 1, wherein the conductive metal layer comprises one or more of copper (Cu), ruthenium (Ru), manganese (Mn), cobalt (Co), molybdenum (Mo), tungsten (W), and tantalum (Ta).

5. The method of claim 4, wherein the conductive metal layer comprises copper (Cu).

6. The method of claim 1, wherein the seed layer comprises ruthenium (Ru).

7. The method of claim 1, wherein the metal precursor comprises a metal selected from one or more of copper (Cu), ruthenium (Ru), manganese (Mn), cobalt (Co), molybdenum (Mo), and tungsten (W).

8. The method of claim 1, wherein the gap fill material comprises one or more of copper (Cu), ruthenium (Ru), manganese (Mn), cobalt (Co), molybdenum (Mo), and tungsten (W).

9. The method of claim 8, wherein the gap fill material comprises molybdenum (Mo).

10. The method of claim 1, further comprising pre-cleaning the substrate prior to exposing the substrate to the first reactant and the ruthenium precursor.

11. The method of claim 1, wherein the seed layer comprises greater than or equal to about 99 % ruthenium atoms.

12. A method of manufacturing a semiconductor device, the method comprising:
forming a dielectric layer on a conductive metal layer on a substrate, the dielectric layer including at least one feature defining a gap having sidewalls and a bottom;
pre-cleaning the substrate;
depositing a seed layer on the conductive metal layer by exposing a top surface of a substrate to a first reactant and a ruthenium precursor; and
performing a gap fill process to fill the gap with a gap fill material.

13. The method of claim 12, wherein the seed layer has a thickness in a range of from greater than 0 Å to 10 Å.

14. The method of claim 13, wherein the seed layer has a thickness in a range of from greater than 0 Å to 5 Å.

15. The method of claim 12, wherein the conductive metal layer comprises one or more of copper (Cu), ruthenium (Ru), manganese (Mn), cobalt (Co), molybdenum (Mo), tungsten (W), and tantalum (Ta).

16. The method of claim 15, wherein the conductive metal layer comprises copper (Cu).

17. The method of claim 12, wherein the seed layer comprises ruthenium (Ru).

18. The method of claim 12, wherein the gap fill material comprises a metal selected from one or more of copper (Cu), ruthenium (Ru), manganese (Mn), cobalt (Co), molybdenum (Mo), and tungsten (W).

19. The method of claim 18, wherein the gap fill material comprises molybdenum (Mo).

20. The method of claim 12, wherein the gap fill process comprises exposing the seed layer to a second reactant and a metal precursor to form the gap fill material.
